(19) United States
(12) Patent Application Publication
(10) Pub. No.: US 2025/0157881 A1
(43) Pub. Date: May 15, 2025

(54) OPTIMIZED COMBINED MICROCHANNEL AND HEAT PIPES FOR ELECTRONICS COOLING

(71) Applicant: Kambix Innovations II, LLC, Albuquerque, NM (US)

(72) Inventors: Kambiz Vafai, Mission Viejo, CA (US); Khavar Fazeli, Riverside, CA (US)

(21) Appl. No.: 18/923,447

(22) Filed: Oct. 22, 2024

Related U.S. Application Data
(60) Provisional application No. 63/545,355, filed on Oct. 23, 2023.

(51) Int. Cl. H01L 23/427

(52) U.S. Cl. CPC H01L 23/427

(57) ABSTRACT

A three dimensional (3D) integrated circuit (IC) chip can include a multi-layer structure comprising a group of vertically stacked semiconductor layers. The multi-layer structure can include a group of processor cores distributed across the semiconductor layers, and a group of Through Silicon Vias (TSVs) arranged within the layers to facilitate electrical connections between the layers. The 3D IC chip can be optimized for thermal management based on a predictive model, enabling effective temperature control when utilized with a thermal management system that monitors and adjusts a cooling strategy of the 3D IC chip.

### CROSS REFERENCE TO PROVISIONAL APPLICATION

This patent application claims priority under 35 U.S.C. § 119 to U.S. Provisional Patent Application Ser. No. 63/545,355 entitled “Optimized Combined Microchannel and Heat Pipes for Electronics Cooling,” which was filed on Oct. 23, 2023, and is incorporated herein by reference in its entirety.

### TECHNICAL FIELD

Embodiments are related to the dissipation of heat in electronic components. Embodiments are also related to thermal management systems for electronic devices. Embodiments further relate to heat sinks utilized with electronic components. Embodiments also relate to microchannels and heat pipes for electronics cooling.

### BACKGROUND

Dissipation of heat created in electronic components has always been a challenge. As electronic devices get more compact and powerful, the need for effective thermal management systems becomes even more crucial. Without proper thermal management systems, the heat generated by these devices can cause significant temperature rises that can impact their performance and reliability. To ensure optimal functionality, it is essential to remove the generated heat effectively with lower temperature rise and uniform temperature distribution within the electronic component. In applications with high cooling capacity and packing density requirements, contained liquid-forced cooling is one of the attractive choices. An effective cooling method is to mount a microchannel heat sink (MCHS) on the idle side of the electronic component. The cooling fluid flows through the micro-scale channels, picking up the dissipated heat. The first microchannel heat sink was introduced by Tuckerman and Pease in 1981 [1] and was considered a milestone in heat sink technology. Microchannel heat sinks have significantly lower thermal resistance than conventional heat sinks. Their effectiveness is explained by Newton's law of cooling and the definition of the Nusselt number as indicated by equation (1):

$$Nu = \frac{{hd}_{H}}{{k}_{f}} \qquad ( 1 )$$

In fully developed laminar flow, the Nusselt number is constant [2], and assuming constant fluid properties, as indicated by equation (2):

$$h ∝ \frac{1}{{d}_{H}} \qquad ( 2 )$$

The smaller the channel's hydraulic diameter is, the more significant the heat transfer coefficient. Additionally, dividing the macro size channel into hundreds of microscale channels significantly increases the heat transfer area of the heat sink. Increased heat transfer coefficient and cooling surface are the main reasons that microchannel heat sinks are more effective thermally compared to regular heat sinks. However, some challenges associated with MCHSs need to be addressed. One of the main challenges is the stream-wise temperature rise in MCHSs which creates a temperature gradient on the cooling surface, leading to thermal stress and damage to electronic chips. Another challenge is the decreased size of channels which increases the friction forces between the liquid and channel walls, resulting in an increased pressure drop, another challenge associated with MCHSs.

Many studies have been conducted to improve the thermal and hydraulic performance of MCHS. One of the most significant innovations in MCHS design is double-layer and multi-layer MCHSs, first established by Vafai and Zhu [3-5]. Vafai and Zhu [3] demonstrated that utilizing two layers of MCHS with counter flow configuration on top of each other decreases the stream-wise temperature rise dramatically compared to regular single-layer MCHS. It also offers a more uniform temperature distribution. Many other numerical and experimental studies have shown that double-and multi-layer MCHS designs have higher thermal capability than single-layer ones. Wei and Joshi [6] investigated multi-layer MCHS with flexible control over each layer's flow direction and flow rate. This study indicates that multi-layer MCHSs are more efficient regarding pumping power requirements. Patterson et al. [7] numerically investigated the heat transfer inside stacked microchannels with different flow arrangements. They reported that the counter flow arrangement proved to have the most uniform temperature distribution for the range of flow rates they studied. In contrast, the parallel flow configuration performs best in reducing the peak temperature. The same results were reported by Wei et al. [8, 9].

Levac et al. [10] investigated the effect of Reynolds number, inlet velocity profile, and flow configuration in the channels of the MCHS. They found that within the range 116≤Re≤1160, the two-layer MCHS with counter flow has the lowest peak temperature, while the peak temperature in parallel flow arrangement is lower at Re<˜100. Wong and Muezzin [11] also established that counter flow configuration is superior to parallel flow for high Reynolds numbers. Regarding the uniformity of temperature on the chip, the counter flow arrangement performed better than parallel flow at all values of Re.

Lin et al. [12, 13] performed a thorough parametric investigation on double and multi-layer MCHS to better understand the design factors concerning channel dimensions, pumping power distribution, and flow configuration. They established that the optimized flow configuration is (0,1), (0,1,1), (0,1,1,1), respectively, for two-, three- and four-layer MCHSs (‘0’ stands for flow in positive x-direction and ‘1’ stands for flow in negative x-direction). Their result shows that the counter flow arrangement is more effective when applied to the first two layers of channels. In their research, Khaled and Vafai [14] employed rotatable plates to separate the layers in double-layered microchannels to increase the cooling in MCHS. Their findings indicated that double-layer flexible MCHS with rotatable plates outperformed equivalent rigid configurations in terms of cooling efficiency within specific ranges of Reynolds numbers, stiffness, and aspect ratios. Chuan et al. [15] proposed a double-layered microchannel heat sink featuring truncated top channels, resulting in a substantial reduction in thermal resistance compared to the original design. Their study showed that for a double-layered MCHS with a counter-flow arrangement, certain regions close to the outlet of the second layer channels, especially at low Reynolds numbers, experience an adverse heat transfer from the fluid to the adjacent solid. Chuan et al.'s innovative design with truncated top channels effectively mitigates this undesired heating effect. Lu and Vafai [16] thoroughly compared innovative MCHSs, including two-layer and multi-layer MCHS, showing that double-layer and multi-layer MCHS have lower thermal resistance and temperature gradient, and require less pumping power.

Japer et al. [17] investigated a novel MCHS design incorporating cavities and ribs within a secondary channel. Their findings highlight the exceptional overall performance of their proposed design with triangular cavities, rectangular ribs, and secondary channel (TC-RR-SC), attributed to the redevelopment of the thermal

boundary layer and the mixing of flow within the primary channel. Lori and Vafai [18] investigated the heat transfer and hydraulic performance of a microchannel, focusing on the impact of incorporating vertical porous ribs with different trapezoidal configurations. The study evaluates the Nusselt number, pressure drop, and figure of merit (FOM), a metric assessing both heat transfer and hydraulic efficiency, comparing these parameters to a microchannel without a porous medium. Their findings revealed a noteworthy reduction in pressure drop when porous ribs were used, in comparison to solid configurations, while achieving the same increase in the Nusselt number.

Hung et al. [19] investigated the effect of coolant characteristics on the thermal performance of MCHSs. Their study demonstrated that using coolants with high thermal conductivity and specific heat, as well as low dynamic viscosity, enhances the thermal performance of MCHSs. Hung and Yan [20] studied the thermal performance of a double-layered Microchannel Heat Sink (MCHS) while incorporating nanofluids and varying geometric parameters. Their analysis indicates that the type of nanofluid, particle volume fraction, number of channels, channel width ratio, channel aspect ratio, and pumping power impact the thermal resistance of the MCHS. Their study reveals that employing a water based Al₂O₃ nanofluid (with a concentration of 1%) leads to 26% increase in thermal performance of MCHS compared to pure water under conditions of fixed pumping power. However, the effectiveness of nanofluid diminishes dramatically at higher pumping power levels, emphasizing the need for appropriate adjustments to the geometric parameters. Jung and Park [21] investigated the velocity and temperature distributions of Al₂O₃ nanofluid and deionized (DI) water within a MCHS using the particle image velocimetry (PIV) and laser-induced fluorescence (LIF) measurement techniques.

Heat pipes can also substantially enhance electronic cooling. A heat pipe is a vacuum sealed metal tube with a thin wick layer on the internal surface. It contains a working fluid that circulates within the device and transfers heat from hot spots to cooler regions. When heat is introduced to a section of the heat pipe, called the evaporator section, the working fluid evaporates, and the hot vapor travels to the colder region, called the condenser section, where it condenses back to liquid. The capillary action forces the condensed liquid to travel back from the condenser to the

evaporator section through the wick's porous structure [22]. The phase change allows the heat pipe to provide efficient and uniform cooling across large surfaces without needing external power input or moving parts.

Heat pipe transfer heat much more efficiently than solid metal with a significantly lighter weight. They can also be combined with other cooling methods for additional thermal management. Traditional heat pipes are limited by their round shape, which makes it challenging to provide an effective cooling surface on smaller heat sources. Multi-channel Flat shaped heat pipes, established and investigated by Vafai et al. [23-27], overcome these limitations by providing better geometric adaptability and the ability to operate reliably under asymmetrical heat load conditions. Ahmadian et al. [28] investigated an innovative cooling system that combines a microchannel heat sink with pulsating heat pipes. Their study indicated that the pulsating heat pipes effectively reduce thermal resistance and outperform conventional methods for enhancing microchannel heat sink performance at the same pumping power. Other pertinent electronic cooling issues have been considered in the literature [29-33].

The trend toward miniaturization and intricate design has resulted in markedly uneven power distribution within processors, leading to localized areas with significantly higher power density than the chip's overall average, giving rise to what's known as a hot spot. These hot spots have a negative impact on processor performance and reliability while also reducing cooling efficiency [34, 35]. Most previous MCHS studies have relied on the assumption of a constant heat flux at the base area, which meant to represent a uniform heat generation by the chip. The applications with local high heat flux, which can exceed ten times the average heat flux generated by the electronic substrate, are mostly overlooked.

### BRIEF SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings, and abstract as a whole.

It is, therefore, one aspect of the disclosed embodiments to provide for improved integrated circuits.

It is another aspect of the disclosed embodiments to provide for an improved heat sink.

It yet another aspect of the disclosed embodiments to provide for an optimized combined microchannel and heat pipes for electronic cooling of electronic components such as integrated circuits.

The aforementioned aspects and other objectives and advantages can now be achieved as described herein.

In an embodiment, a heat sink can comprise a microchannel heat sink (MCHS).

In an embodiment, a heat sink can comprise a flat plate micro heat pipe (FPM-HP).

In an embodment, a hybrid heat sink, can comprise: a microchannel heat sink (MCHS); and a flat plate micro heat pipe (FPM-HP), wherein the MCHS and FPM-HP are combined to optimize hotspot management in electronics cooling applications that involve local high heat generation.

In an embodiment, the MCHS and FPM-HP can be combined in a parallel flow configuration.

In an embodiment, the MCHS and FPM-HP can be combined in a counter flow configuration.

The embodiments include innovative heat sink designs including Microchannel Heat Sinks (MCHS) and Flat Plate Micro Heat Pipes (FPM-HP) that improve thermal management in electronic components. A three-dimensional finite volume method is used to analyze the fluid flow and heat transfer in the heat sinks. The validity of the numerical models is confirmed by comparison with pertinent experimental data. The thermal performances of the new heat sink designs are compared to that of double-layer microchannel heat sinks with parallel flow (DLPF MCHS) and counter flow (DLCF MCHS) configurations, as two of the more efficient heat sink designs in the industry.

The investigated configuration of Silicon-Water Counter Dual MCHS with rectangular cross-section improves the temperature uniformity by 43-50% and 26-31% compared to DLPF and DLCF MCHSs, respectively, and the triangular cross-section configuration improves it by 38-47% and 21-26%, respectively. The thermal resistance of heat sinks is reduced by 10-15% compared to DLPF MCHS and by 2-8% compared to DLCF MCHS.

Additionally, innovative hybrid heat sink designs combined with MCHS and FPM-HP are proposed to optimize hotspot management in electronics cooling applications that involve local high heat generation. The hybrid DLPF MCHS & FPM-HP reduces the maximum temperature and surface temperature gradient of the heat sink by 13-23% and 20-49%, while these are reduced by 16-40% and 27-64% for the hybrid DLCF MCHS & FPM-HP compared with the corresponding copper base (no heat pipe) designs. The hybrid Counter Dual Rectangular MCHS & FPM-HP reduces the maximum temperature and surface temperature gradient of the heat sink by 15-24% and 29-65% compared with the DLCF MCHS with copper base (no heat pipe) design, while these are reduced by 10-26% and 24-63% for the Counter Dual Triangular MCHS, respectively.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a schematic view of a studied MCHS with (a) Double-Layer Parallel Flow MCHS, (b) Double-Layer Counter Flow MCHS, (c) Counter Dual Rectangular MCHS, (d) and Counter Dual Triangular MCHS, in accordance with an embodiment;

FIG. 2 illustrates of the computational domain for MCHS Study (schematic elements as described in FIG. 1), in accordance with an embodiment;

FIG. 3 illustrates a schematic diagram of a Hybrid Heat Sink design combined with Double-Layer MCHS and Flat Plate Micro Heat Pipe, in accordance with an embodiment;

FIG. 4 illustrates a schematic diagram of the computation domain used for the analysis of the Hybrid Heat Sink design combined with Double-Layer Parallel Flow MCHS and Flat Plate Micro Heat Pipe, in accordance with an embodiment;

FIG. 5 illustrates a schematic diagram of the hybrid heat sink design combined with Counter Dual Rectangular MCHS and Flat Plate Micro Heat Pipe, in accordance with an embodiment;

FIG. 6 illustrates a schematic diagram of a hybrid heat sink design combined with Counter Dual Triangular MCHS and elate Micro Heat Pipe, in accordance with an embodiment;

FIG. 7 illustrates a graph depicting data derived from an MCHS model grid independence study with the temperature along line ‘d’ at z=−0.5 L_{ch}, in accordance with an embodiment;

FIG. 8 illustrates a graph depicting validation with experimental data including a bottom wall temperature distribution for double layer parallel flow MCHS, in accordance with an embodiment;

FIG. 9 illustrates a graph depicting validation with experimental data including a bottom wall temperature distribution for double layer counter flow MCHS, in accordance with an embodiment;

FIG. 10 illustrates a graph depicting data indicative of a hybrid heat pipe and MCHS model grid independence study with temperature along line ‘d’ at z=−0.5 Lch, in accordance with an embodiment;

FIG. 11 illustrates graphs depicting a comparison of the model results with previous numerical and experimental data in the literature, a) Wall Temperature, b) Vapor Temperature, in accordance with an embodiment;

FIG. 12 illustrates graphs depicting a comparison of the thermal resistance and the cooling surface temperature gradient of the studied heat sinks (Silicon-Water), in accordance with an embodiment;

FIG. 13 illustrates graphs depicting a comparison of the maximum temperature of the studied heat sinks (Silicon-Water), in accordance with an embodiment;

FIG. 14 illustrates graphs depicting a comparison of the thermal resistance and the cooling surface temperature gradient of the studied heat sinks (Copper-Water), in accordance with an embodiment;

FIG. 15 illustrates graphs depicting a comparison of the maximum temperature of the studied heat sinks (Copper-Water);

FIG. 16 illustrates graphs depicting a comparison of the pumping power and Reynolds number of the studied heat sinks (similar results for Silicon-Water and Copper-Water MCHS), in accordance with an embodiment;

FIG. 17 illustrates a graph depicting data indicative of the impact of the aspect ratio of the channel on the thermal resistance of the triangular MCHS (while keeping the channel cross-sectional area constant), in accordance with an embodiment;

FIG. 18 illustrates temperature distribution of the heat sink in axial cross section at x=0, in accordance with an embodiment;

FIG. 19 illustrates graphs depicting a comparison of the maximum temperature and the cooling surface temperature gradient of the studied hybrid heat sinks, in accordance with an embodiment;

FIG. 20 illustrates the velocity field in the heat pipe as part of the hybrid Counter Dual Rectangular MCHS & Flat Plate Micro Heat Pipe, in accordance with an embodiment;

FIG. 21 illustrates the velocity field in the heat pipe as part of the hybrid Counter Dual Triangular MCHS & Flat Plate Micro Heat Pipe, in accordance with an embodiment; and

FIG. 22 illustrates the velocity field in the heat pipe as part of the hybrid Double-Layer Parallel Flow MCHS & Micro Heat Pipe heat sink, in accordance with an embodiment.

### DETAILED DESCRIPTION

The particular values and configurations discussed in these non-limiting examples can be varied and are cited merely to illustrate one or more embodiments and are not intended to limit the scope thereof.

Subject matter will now be described more fully hereinafter with reference to the accompanying drawings, which form a part hereof, and which show, by way of illustration, specific example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware, or any combination thereof (other than software per se). The following detailed description is, therefore, not intended to be interpreted in a limiting sense.

Throughout the specification and claims, terms may have nuanced meanings suggested or implied in context beyond an explicitly stated meaning. Likewise, phrases such as “in one embodiment” or “in an example embodiment” and variations thereof as utilized herein do not necessarily refer to the same embodiment and the phrase “in another embodiment” or “in another example embodiment” and variations thereof as utilized herein may or may not necessarily refer to a different embodiment. It is intended, for example, that claimed subject matter include combinations of example embodiments in whole or in part. In addition, identical reference numerals utilized herein with respect to the drawings can refer to identical or similar parts or components.

In general, terminology may be understood, at least in part, from usage in context. For example, terms such as “and,” “or,” or “and/or” as used herein may include a variety of meanings that may depend, at least in part, upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein, depending at least in part upon context, may be used to describe any feature, structure, or characteristic in a singular sense or may be used to describe combinations of features, structures, or characteristics in a plural sense. Similarly, terms such as “a,” “an,” or “the”, again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The embodiments focus on optimizing MCHS designs for electronic cooling applications with constant heat flux at the base. MCHSs with rectangular and triangular cross-sections and counter flow arrangement in adjacent channels (Counter Dual MCHSs) are thoroughly investigated. Next, innovative combined Heat Sink designs that utilize MCHS and Flat Plate Micro Heat Pipe (FPM-HP) are introduced. These hybrid designs are particularly beneficial for managing hotspots in electronic cooling applications that involve local high heat generation. Combining MCHS and HP technologies can achieve optimal cooling performance and ensure that the electronic device operates efficiently.

### Approach and Methodologies

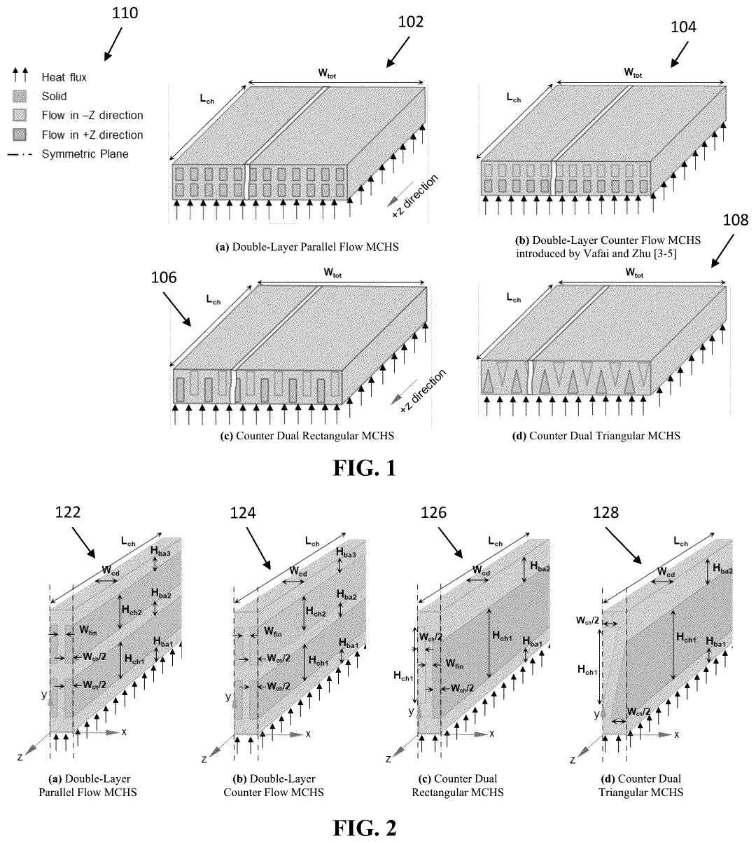

MCHS designs with counter flow arrangement in adjacent channels (Counter Dual MCHSs). Two MCHS designs can utilize counter flow arrangement in adjacent channels, which can be referred to as Counter Dual MCHSs herein. FIG. 1 illustrates a schematic view of a studied MCHS with (a) Double-Layer Parallel Flow MCHS 102, (b) Double-Layer Counter Flow MCHS 104, (c) Counter Dual Rectangular MCHS 106, (d) and Counter Dual Triangular MCHS 108, in accordance with an embodiment. The disclosed Counter Dual MCHS geometries feature rectangular and triangular channel cross-sectional configurations, as depicted in FIG. 1—(c) and (d).

FIG. 2 illustrates of the computational domain for MCHS Study (schematic elements as described in FIG. 1), in accordance with an embodiment. In FIG. 2, (a) Double-Layer Parallel Flow MCHS 122, (b) Double-Layer Counter Flow MCHS 124, (c) Counter Dual Rectangular MCHS 126, (d) and Counter Dual Triangular MCHS 128, are shown.

To simulate the fluid flow and conjugate heat transfer in MCHSs, a three-dimensional model using the finite volume discretization method was developed with the COMSOL Multiphysics program. To reduce computational costs, the computational domain is selected by considering symmetry when investigating counter flow arrangement in the adjacent channels. The schematic view of the MCHSs and their corresponding computational domains are therefore illustrated in FIGS. 1 and 2, respectively.

Based on previous studies [3, 36-41], this investigation makes several assumptions, including 1) steady-state condition, 2) incompressible and laminar flow, 3) negligible viscous dissipation and gravity effect, 4) constant thermophysical properties in the fluid and solid, 5) negligible entrance and exit effect at the inlet and outlet. The governing equations for the fluid region include the following.

Conservation of mass,

$$∇ \cdot \vec{V} = 0 \qquad ( 3 )$$

Conservation of momentum,

$${ρ}_{l} ( \vec{V} \cdot ∇ ) \vec{V} = - ∇ p + {μ}_{l} {∇}^{2} \vec{V} \qquad ( 4 )$$

Conservation of energy for the liquid region,

$${ρ}_{l} {c}_{p , l} ( \vec{V} \cdot ∇ ) {T}_{l} = {k}_{l} {∇}^{2} {T}_{l} \qquad ( 5 )$$

And the energy equation for the solid,

$${k}_{s} {∇}^{2} {T}_{s} = 0 \qquad ( 6 )$$

where \vec{V}, p, and T are the velocity vector, pressure, and temperature, respectively. Subscripts l refers to liquid, and s indicates solid properties.

Uniform heat flux is applied at the microchannel's bottom wall, accounting for the heat generated in the electronic substrate. To concentrate on the heat removal by the set-up, the upper wall of the heat sink is considered not to remove much heat and as such, heat is not dissipated from the top wall. The conductive heat from the solid walls at the inlet and outlet is neglected and concentrate on the heat removal from the device, the adiabatic boundary condition is applied to all external walls in the computational domain except for the bottom wall. At the inlet, a constant fluid temperature is assumed, while the adiabatic condition is applied at the outlet. The atmospheric pressure condition is applied at the outlet, and a pressure boundary condition with no viscous stress is applied at the inlet to maintain a fixed pressure drop along the channel. However, for fixed flow rate cases, a fully developed velocity condition is used at the inlet. At all solid-liquid interfaces, no-slip boundary conditions and continuous temperature and heat flux are employed. These assumptions are consistent with previous analyses [3, 7, 36-41].

The thermal resistance is defined as

$${R}_{T} = \frac{{T}_{max} - {T}_{min}}{{q}^{″} A} \qquad ( 7 )$$

where Tₘₐₓ represent the hottest temperature in the heat sink and Tₘᵢₙ is the lowest temperature in the heat sink, which is the same as the coolant inlet temperature. A represent the cooling surface area and q″ is the applied heat flux at the base surface of the heat sink.

The cooling surface temperature gradient of the heat sink can be defined as the difference between the maximum and minimum temperatures at the bottom wall of the heat sink, where the heat flux is applied. The pumping power is calculated according to below equation:

$$Pumping power = Q \cdot Δ P \qquad ( 8 )$$

Where Q is the volumetric flow rate of the coolant and ΔP is the pressure drop.

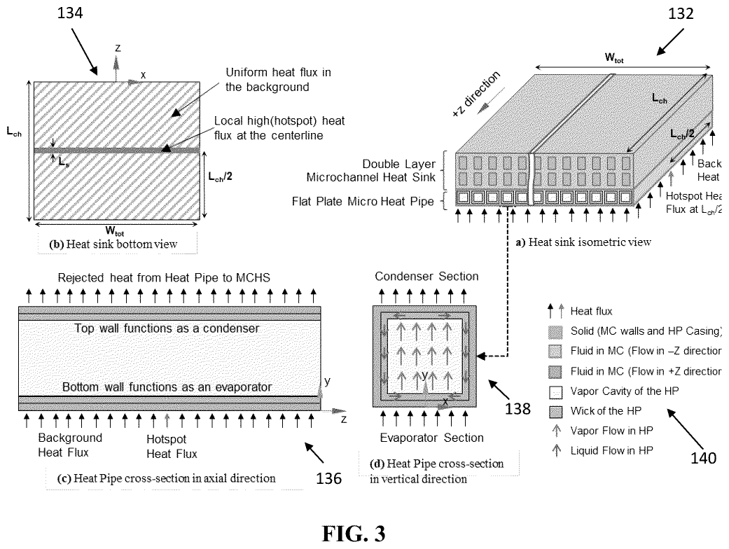

Hybrid Heat Sink designs combined with MCHS and Flat Plate Micro Heat Pipe (FPM-HP). Innovative hybrid heat sink designs combined with FPM-HP and MCHSs are investigated to optimize hotspot management in electronics cooling. The schematic of the studied hybrid heat sink designs with their corresponding computational domains are depicted in FIGS. 3-6. The governing equations and assumptions used for the MCHS section of these heat sinks are consistent with our previous study in section 2.1. The following are governing equations and assumptions used at various regions of the heat pipe.

FIG. 3 illustrates a schematic diagram of a Hybrid Heat Sink design combined with Double-Layer MCHS and Flat Plate Micro Heat Pipe, in accordance with an embodiment. In FIG. 3, a heat sink isometric view 132 is shown along with a heat sink bottom view 134 and a heat pipe 136 with a cross-section in an axial direction. A heat pipe 138 cross section is shown in the vertical direction. A legend 140 is shown in FIG. 3 with respect to various illustrated components, elements and features.

FIG. 4 illustrates a schematic diagram of the computation domain used for the analysis of the Hybrid Heat Sink design combined with Double-Layer Parallel Flow MCHS and Flat Plate Micro Heat Pipe, in accordance with an embodiment. FIG. 4 depicts an isometric view and a cross-sectional view 144 in the vertical direction.

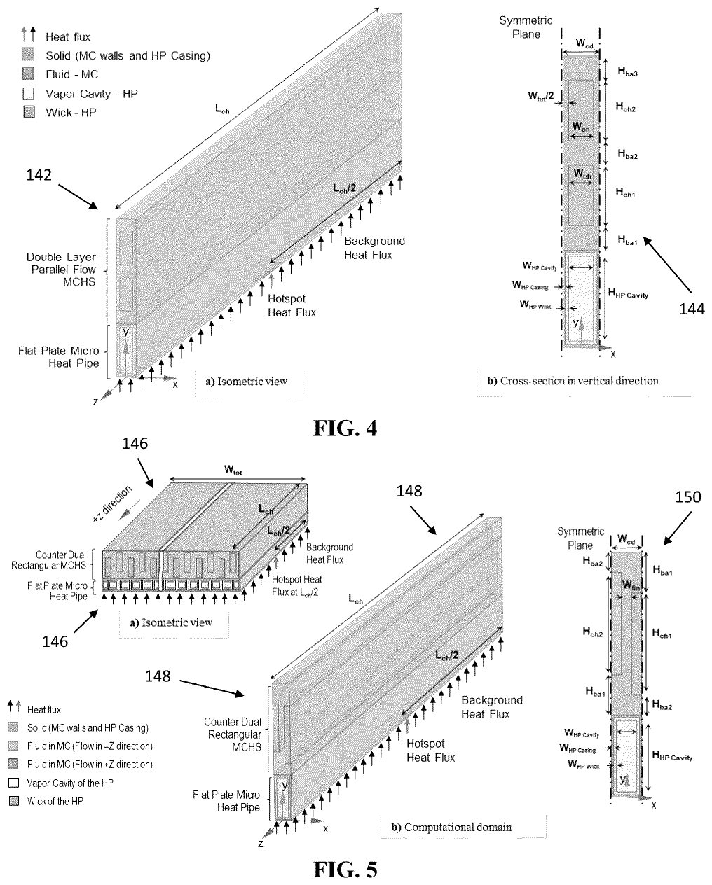

FIG. 5 illustrates a schematic diagram of the hybrid heat sink design combined with Counter Dual Rectangular MCHS and Flat Plate Micro Heat Pipe, in accordance with an embodiment. FIG. 5 depicts an isometric view 146, a computational domain 148, and a symmetric plane 150.

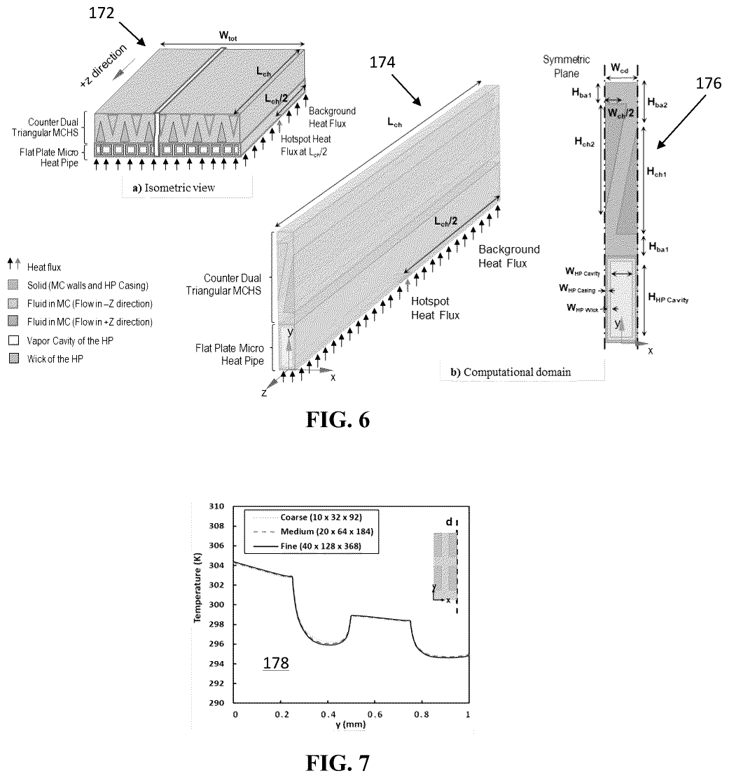

FIG. 6 illustrates a schematic diagram of a hybrid heat sink design combined with Counter Dual Triangular MCHS and Flat Plate Micro Heat Pipe, in accordance with an embodiment. FIG. 6 depicts an isometric view 172, a computational domain 174, and a symmetric plane 176.

Cavity (vapor) region: The assumptions made for the Cavity (vapor) region include 1) steady-state condition, 2) compressible and laminar flow, 3) negligible viscous dissipation and gravity effect, 4) constant thermo-physical properties.

Conservation of mass,

$$∇ \cdot \vec{{V}_{v}} = 0 \qquad ( 9 )$$

Conservation of momentum,

$${ρ}_{v} ( \vec{{V}_{v}} \cdot ∇ ) \vec{{V}_{v}} = - ∇ {p}_{v} + {μ}_{v} {∇}^{2} \vec{{V}_{v}} \qquad ( 10 )$$

Conservation of energy,

$${ρ}_{v} {c}_{p , v} ( \vec{{V}_{v}} \cdot ∇ ) {T}_{v} = {k}_{v} {∇}^{2} {T}_{v} \qquad ( 11 )$$

### Cavity-Wick Interface:

It is assumed that phase change occurs solely at the cavity-wick interface. The coupled boundary condition is applied, and Water (in the wick) and vapor (in the cavity) are assumed at equilibrium.

$${p}_{v} = {p}_{{H}_{2} O , sat} ( T ) \qquad ( 12 )$$

Boundary continuity and boundary heat flux is introduced at the Water (in wick) and vapor (in cavity) interface to introduce phase change.

$${ρ}_{l} \vec{{V}_{l}} = {ρ}_{v} \vec{{V}_{v}} \qquad ( 13 )$$

$$Q = {\dot{m}}_{v} {h}_{f g} ( T ) \qquad ( 14 )$$

### Wick (Porous) Region:

The assumptions made for the wick region include 1) no dry-out condition (wick is saturated with liquid), 2) the capillary pressure is enough to force the condensate back to the evaporator region, 3) steady-state condition, 4) compressible flow, 5) negligible inertial term and gravity effect (horizontal position), 6) constant thermo-physical properties.

Conservation of mass,

$$∇ \cdot \vec{{V}_{l}} = 0 \qquad ( 15 )$$

Conservation of momentum, according to Vafai and Tien [42],

$$0 = - ∇ {p}_{l} + {μ}_{l} {∇}^{2} \vec{{V}_{l}} - {μ}_{l} \frac{ϵ}{K} \vec{{V}_{l}} \qquad ( 16 )$$

Conservation of energy (Liquid),

$${ρ}_{l} {c}_{p , l} ( \vec{{V}_{l}} \cdot ∇ ) {T}_{l} = {k}_{e f f} {∇}^{2} {T}_{l} \qquad ( 17 )$$

### Solid Casing Region

Conservation of energy,

$$0 = {k}_{s} {∇}^{2} {T}_{s} \qquad ( 18 )$$

### Model Validation

FIG. 7 illustrates a graph 178 depicting data derived from an MCHS model grid independence study with the temperature along line ‘d’ at z=−0.5 L_{ch}, in accordanc3 with an embodiment.

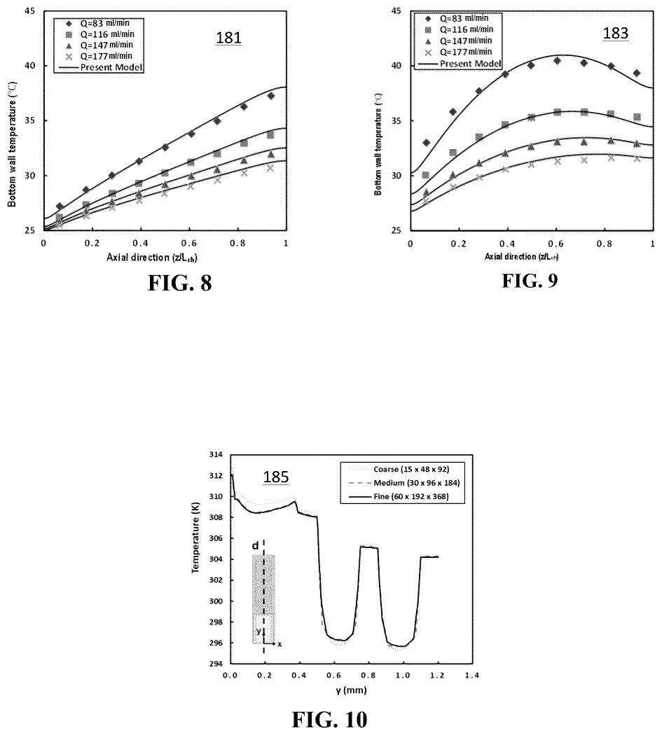

FIG. 8 illustrates a graph 181 depicting validation with experimental data including a bottom wall temperature distribution for double layer parallel flow MCHS, in accordance with an embodiment.

FIG. 9 illustrates a graph 183 depicting validation with experimental data including a bottom wall temperature distribution for double layer counter flow MCHS, in accordance with an embodiment.

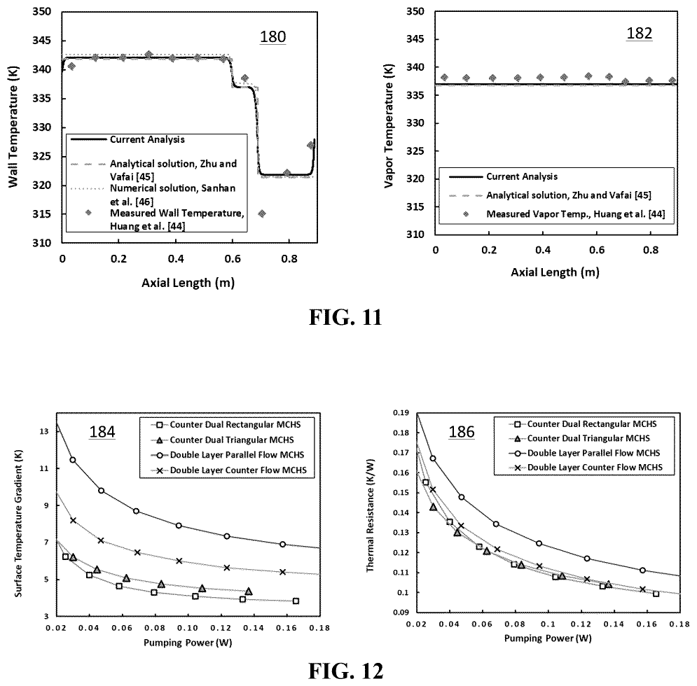

FIG. 10 illustrates a graph 185 depicting data indicative of a hybrid heat pipe and MCHS model grid independence study with temperature along line ‘d’ at z==0.5 Lch, in accordance with an embodiment.

3.1 MCHS model validation. The 3D numerical model developed for MCHSs in this study is validated using experimental data from Wei et al. [43]. To ensure accuracy, grid-independence test is conducted by comparing results using three mesh sizes in a DLPF-MCHS. The fluid and solid temperature profiles estimated by the three mesh distributions at the symmetric line (d) are shown in FIG. 7. Based on the results, the medium grid setting is adopted for this work.

Wei et al. [43] conducted two sets of experiments for both parallel flow and counter flow arrangements at various flow rates. FIGS. 8 and 9 show the bottom wall temperature comparison for parallel and counter flow studies, respectively. The comparisons indicate excellent agreement between the MCHS simulation performed in this study and experimental data.

Heat Pipe model validation. The 3D numerical model of the heat pipe in this study is validated using experimental data reported by Huang et al. [44]. Grid-independence test is conducted by generating results at three grid sizes. Based on the predicted fluid and solid temperature results presented in FIG. 10, the fine grid setting is adopted for this work. To further validate the model, the simulation results were compared with experimental data reported by Huang et al. [44], analytical results from Zhu and Vafai [45], and numerical results from Sanhan et al. [46]. FIGS. 11(a) and (b) show the heat pipe wall and vapor temperature comparison. The results confirm remarkable consistency between the Heat Pipe simulation performed in this study and the cited validation data.

FIG. 11 illustrates graphs 180 and 183 depicting a comparison of the model results with previous numerical and experimental data in the literature, a) Wall Temperature, b) Vapor Temperature, in accordance with an embodiment.

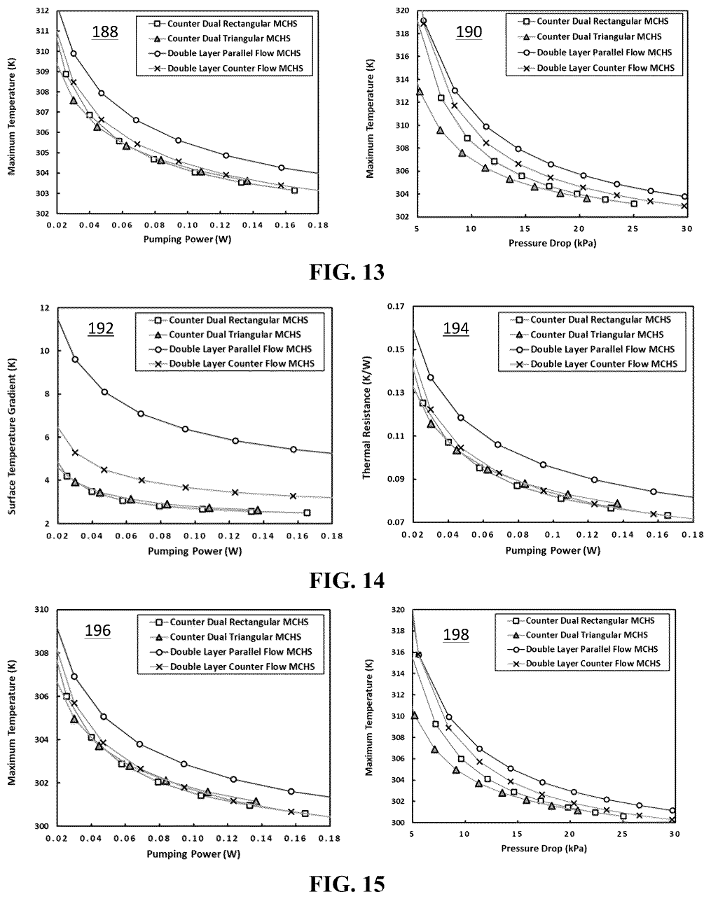

FIG. 12 illustrates graphs 184 and 186 depicting a comparison of the thermal resistance and the cooling surface temperature gradient of the studied heat sinks (Silicon-Water), in accordance with an embodiment.

FIG. 13 illustrates graphs 188 and 190 depicting a comparison of the maximum temperature of the studied heat sinks (Silicon-Water), in accordance with an embodiment.

FIG. 14 illustrates graphs 192 and 194 depicting a comparison of the thermal resistance and the cooling surface temperature gradient of the studied heat sinks (Copper-Water), in accordance with an embodiment.

FIG. 15 illustrates graphs 196 and 198 depicting a comparison of the maximum temperature of the studied heat sinks (Copper-Water).

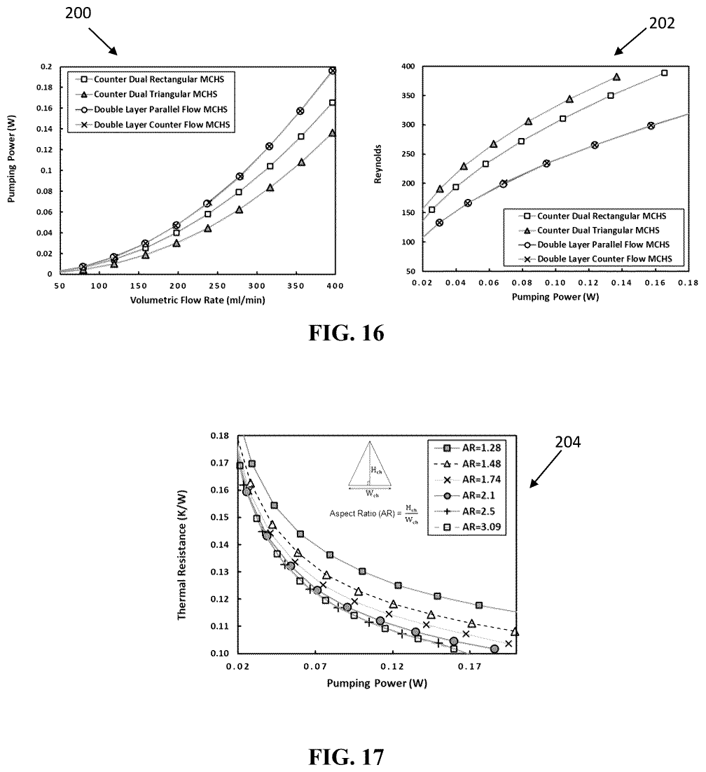

FIG. 16 illustrates graphs 200 and 202 depicting a comparison of the pumping power and Reynolds number of the studied heat sinks (similar results for Silicon-Water and Copper-Water MCHS), in accordance with an embodiment.

FIG. 17 illustrates a graph 204. depicting data indicative of the impact of the aspect ratio of the channel on the thermal resistance of the triangular MCHS (while keeping the channel cross-sectional area constant), in accordance with an embodiment.

4.1 MCHS designs with counter flow arrangement in adjacent channels (Counter Dual MCHSs). The performance of Counter Dual MCHSs with rectangular and triangular channel cross-sections are investigated and compared with DLPF and DLCF-MCHSs. The schematic of these heat sinks and the corresponding computational domains are illustrated in FIG. 2, and the parameters used for this numerical analysis are listed in Table 1. The study is performed for both Silicon-Water and Copper-Water MCHSs, to investigate the impact of MCHS solid material. The maximum temperature, surface temperature gradient, and thermal resistance of the studied MCHSs are compared in FIG. 12 and FIG. 13 for Silicon-Water MCHSs, and the results for Copper-Water MCHSs are shown in FIG. 14 and FIG. 15. The results show that the proposed configuration of Silicon-Water Counter Dual MCHS with rectangular cross-section reduces the surface temperature gradient of the heat sink by 43-50% and 26-31% compared to DLPF and DLCF-MCHSs, respectively. The triangular cross-section also reduces it by 38-47% for parallel and 21-26% for counter flow arrangement, respectively.

Additionally, the studied Counter Dual MCHSs reduce the thermal resistance of heat sinks by 10-15% compared to DLPF-MCHS and by 2-8% compared to DLCF-MCHS. A similar improvement trend is obtained for Copper-Water MCHSs. The required pumping power, Reynolds number, and achieved flow rate are compared in FIG. 16. The Counter Dual MCHSs with rectangular and triangular cross-sections lower pumping power by up to 15% and 30-40%, respectively, in the 50-400 ml/min flow rate range. They both deliver the highest Reynolds number as well.

TABLE 1
Microchannel heat sink parameter specifications used in this work.

| | | | Counter Dual | | Counter Dual | |
|---|---|---|---|---|---|---|
| | DLPF and | | Rectangular | | Triangular | |
| Specification | DLCF MCHS | | MCHS | | MCHS | |
| Material (solid-Liquid) | Copper-Water | | Copper-Water | | Copper-Water | |
| Total length of heat sink | 1 | [cm] | 1 | [cm] | 1 | [cm] |
| (L_{ch}) | | | | | | |
| Total width of heat sink | 1 | [cm] | 1 | [cm] | 1 | [cm] |
| (Wₜₒₜ) | | | | | | |
| Computational domain | 150 | [μm] | 150 | [μm] | 150 | [μm] |
| width (W_{cd}) | | | | | | |
| First layer channel height | 250 | [μm] | 500 | [μm] | 500 | [μm] |
| (H_{ch1}) | | | | | | |
| Second layer channel | 250 | [μm] | — | | — | |
| height (H_{ch2}) | | | | | | |
| Channel width (W_{ch}) | 100 | [μm] | 100 | [μm] | 200 | [μm] |
| Side wall thickness (W_{fin}) | 50 | [μm] | 50 | [μm] | 50 | [μm] |
| Bottom wall thickness (H_{ba1}) | 100 | [μm] | 200 | [μm] | 200 | [μm] |
| Middle wall thickness (H_{ba2}) | 100 | [μm] | — | | — | |
| Top wall thickness (H_{ba3}) | 100 | [μm] | 100 | [μm] | 100 | [μm] |
| Coolant Inlet Temperature | 293.15 | [K] | 293.15 | [K] | 293.15 | [K] |
| Heat flux at the base | 100 | [W/cm²] | 100 | [W/cm²] | 100 | [W/cm²] |

### Approach and Methodologies

The effect of the channel's aspect ratio on the thermal resistance of the triangular cross-section Counter Dual MCHS is also investigated, and results are provided in FIG. 17. When adjusting the aspect ratio (AR) in FIG. 17, both the height (H_{ch}) and the width (W_{ch}) of the microchannel are altered simultaneously, but in a way that maintains the same channel cross-sectional area. This approach allows us to explore the influence of aspect ratio on heat transfer characteristics while keeping the flow area consistent, which is a critical consideration in microchannel heat sink design and performance evaluation. It is observed that the higher the aspect ratio of the channels, the lower the thermal resistance and maximum temperature of the MCHS. However, this trend stops at an aspect ratio of around 3, beyond which increasing the aspect ratio no longer impacts the thermal resistance.

TABLE 2
Heat pipe parameter specifications used in this work.

| Specification | Value | |
|---|---|---|
| Material (Solid-Liquid-Wick) | Copper - Water - Sintered | |
| | copper powder | |
| Total length of heat sink (L_{ch}) | 1 | [cm] |
| Total width of heat sink (Wₜₒₜ) | 1 | [cm] |
| Casing thickness (W_{casing}) | 10 | [μm] |
| Cavity width (W_{cavity}) | 100 | [μm] |
| Wick layer thickness (W_{wick}) | 100 | [μm] |
| Wick porosity (ε) | 0.9 | |
| Wick permeability (K) | 1.5e−9 | [m²] |
| Background heat flux at the base | 100 | [W/cm²] |
| Hotspot heat flux at the base centerline | 600 or 1000 | [W/cm²] |
| Width of hotspot heat flux (Lₛ) | 600 | [μm] |

4.2 Hybrid Heat Sink design combined with MCHS and Flat Plate Micro Heat Pipe (FPM-HP). Innovative hybrid heat sink designs have been developed to optimize thermal and hot spot management in electronic cooling applications with local high heat generation at the base. These designs combine MCHS and FPM-HP technologies. The FPM-HP is inserted between the heat source and the MCHS bottom, to distribute the local high heat flux generated at the base. FIG. 3 shows the schematic view of the hybrid heat sink combined with DL MCHS and FPM-HP. The proposed hybrid heat sinks combined with Counter Dual MCHS and FMP-HP are also provided in FIGS. 5 and 6 for rectangular and triangular cross-sections, respectively. The DL MCHS is investigated at both parallel and counter flow configurations. The studied cases include cooling of electronic substrate that generates 100 W/cm² as background heat flux and high local heat flux of 1000 W/cm² at the centerline of the base. The performance of the hybrid heat sink is compared with DL-MCHSs with a copper heat spreader at the base and with no heat spreader at all (short base). The schematic of the computational domains used for the hybrid heat sinks in this study are presented in FIGS. 4-6. Table 2 lists the parameters used for this numerical analysis.

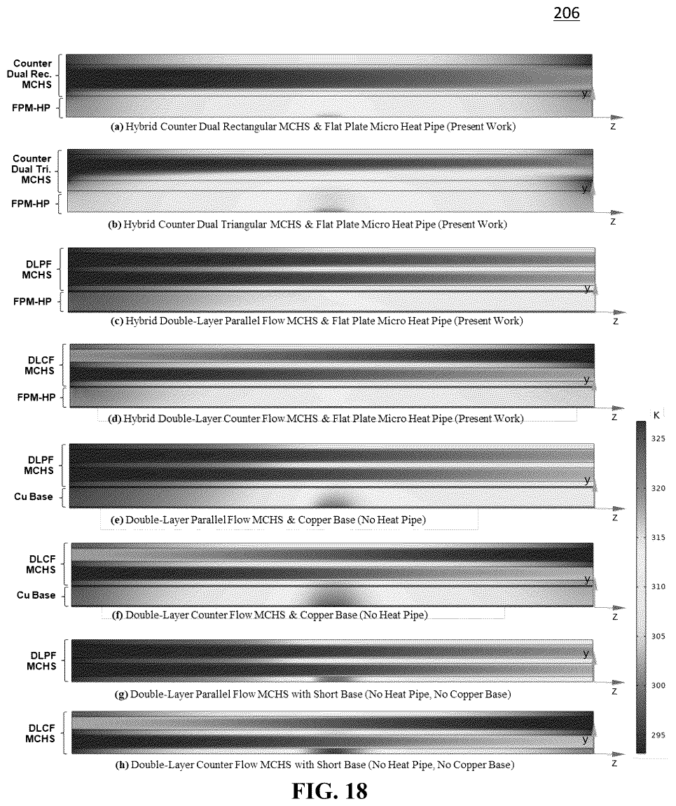

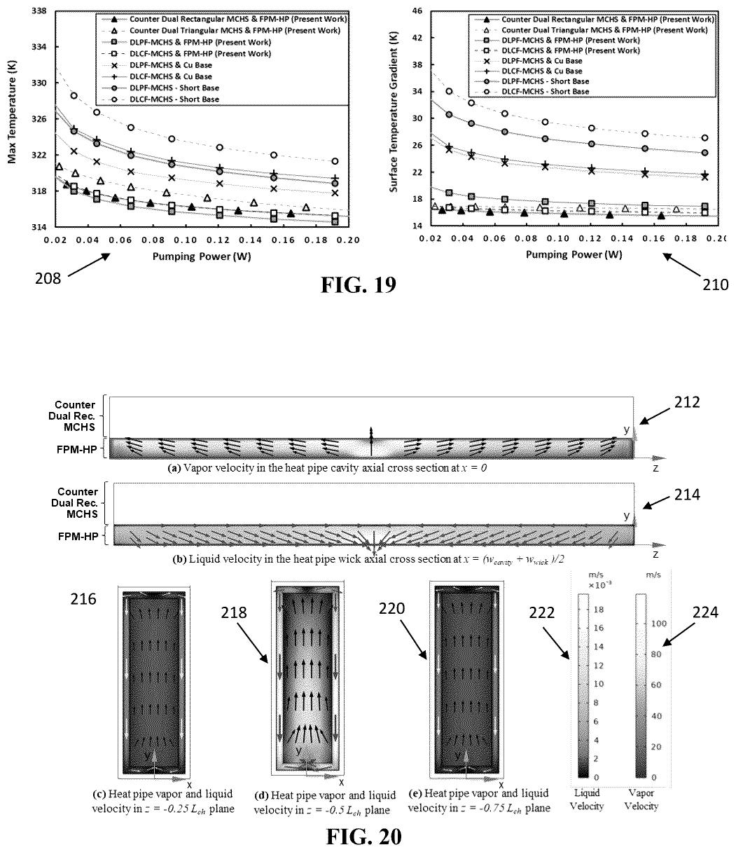

FIG. 18 illustrates a group of graphs 206 depicting temperature distribution of the heat sink in axial cross section at x=0, in accordance with an embodiment. FIG. 18 displays the temperature distributions of the studied heat sinks in axial cross section at 0.05 W pumping power. The maximum temperature and surface temperature gradient of the heat sinks at various pumping powers are compared in FIG. 19. That is, FIG. 19 illustrates graphs 208 and 210 depicting a comparison of the maximum temperature and the cooling surface temperature gradient of the studied hybrid heat sinks, in accordance with an embodiment.

The results show that hybrid heat sinks combined with MCHS & FPM-HP proposed and investigated in this study have the lowest maximum temperature and surface temperature gradient among all the studied designs.

The hybrid DLPF-MCHS & FLM-HP has the lowest maximum temperature followed by the hybrid heat sinks with DLCF, and with Counter Dual Rectangular MCHSs compared to the rest of the studied heat sinks. While the hybrid Counter Dual MCHS & FPM-HP has the lowest surface temperature gradient followed by the hybrid heat sinks with DLCF, and with Counter Dual Triangular MCHSs. In hybrid parallel flow configuration, the coolant temperature is lower at the center of the heat sink where the hot spot of the heat sink is located.

This results in higher temperature difference between the coolant and the base at the hotspot, and therefore an improved maximum temperature, compared to counter flow configuration ones. However, the hybrid counter flow arrangements are superior in terms of temperature uniformity at the base. The hybrid DLPF-MCHS & FPM-HP reduces the maximum temperature and surface temperature gradient of the heat sink by 13-23% and 20-49%, while these are reduced by 16-40% and 27-64% for the DLCF-MCHS & FPM-HP compared with the corresponding copper base (no heat pipe) designs. The hybrid Counter Dual Rectangular MCHS & FPM-HP reduces the maximum temperature and surface temperature gradient of the heat sink by 15-24% and 29-65%, while these are reduced by 10-26% and 24-63% for the Counter Dual Triangular MCHS, respectively, compared with the DLCF MCHS with copper base (no heat pipe) design

FIG. 20 illustrates the velocity field in the heat pipe as part of the hybrid Counter Dual Rectangular MCHS & Flat Plate Micro Heat Pipe, in accordance with an embodiment. FIG. 20 depicts vapor velocity 212 in the heat pipe cavity axial cross section, along with liquid velocity 214 in the heat pipe wick axial cross section. FIG. 20 further depicts representations 216, 218, 220 of heat pipe vapor and liquid velocity along with liquid velocity 222 and 224.

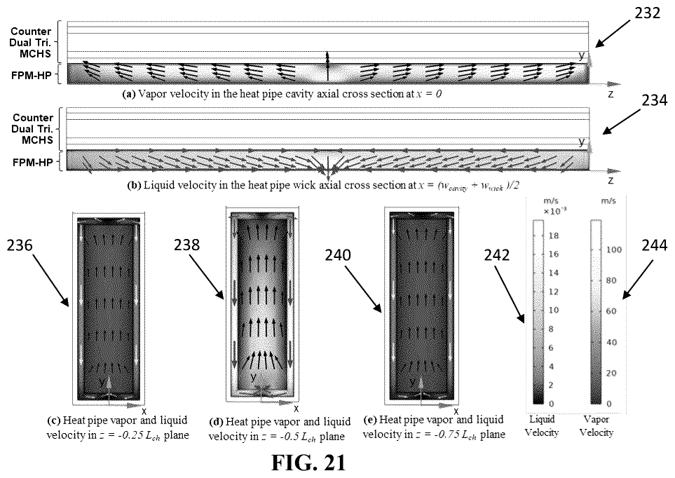

FIG. 21 illustrates the velocity field in the heat pipe as part of the hybrid Counter Dual Triangular MCHS & Flat Plate Micro Heat Pipe, in accordance with an embodiment. FIG. 21 depicts vapor velocity 232 in the heat pipe cavity axial cross section, along with liquid velocity 234 in the heat pipe wick axial cross section. FIG. 21 further depicts representations 236, 238, 240 of heat pipe vapor and liquid velocity along with liquid velocity 242 and 244.

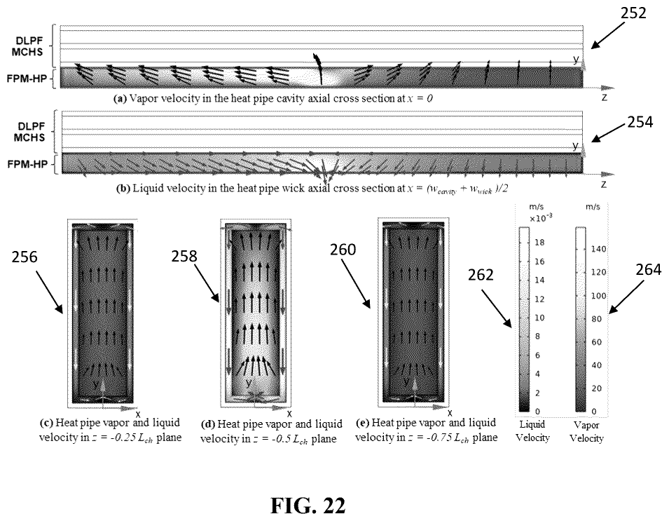

FIG. 22 illustrates the velocity field in the heat pipe as part of the hybrid Double-Layer Parallel Flow MCHS & Micro Heat Pipe heat sink, in accordance with an embodiment. FIG. 22 depicts vapor velocity 252 in the heat pipe cavity axial cross section, along with liquid velocity 254 in the heat pipe wick axial cross section. FIG. 22 further depicts representations 256, 258, 260 of heat pipe vapor and liquid velocity along with liquid velocity 262 and 264.

The velocity field of the vapor and liquid in the heat pipe section of the studied hybrid heat sinks with Counter Dual Rectangular and Triangular MCHSs, and with DLPF MCHSs are shown in FIG. 20, FIG. 21, and FIG. 22, respectively. The results show that the vapor and liquid velocity filed in the heat pipes attached to the counter flow MCHSs are similar in trend and magnitude. In all hybrid heat sinks, the heat pipe's bottom surface acts as an evaporator, and its top surface acts as a condenser section. The water evaporates at the bottom of the heat pipe where it is in contact with the heat source. The vapor then travels to the top surface of the heat pipe, where the microchannel heat sink cools it down and condenses it back to liquid.

The capillary action forces the condensed liquid to travel back to the evaporator section (bottom surface) through the porous structure of the wick. The velocity profile in the vertical and axial cross-section of the heat pipe shows that two sets of coolant circulating loops occur mainly in the heat pipes in this study. The primary circulating loops occur in the vertical cross-sections (xy planes) by vapor and liquid circulating from the bottom to top surface of the heat pipe and return in fixed z height planes, as shown in FIGS. 20-22(c), (d), and (e). The local high heat source at the center of the heat pipe base imposes secondary circulating loops of the water which occur from the bottom center of the heat pipe to the top right and top left side of the heat pipe, as shown in FIGS. 20-22(a) and (b).

The secondary water circulating loop to one side of the heat pipe is more significant than the other, due to the asymmetric nature of the cooling in the MCHS, with coolant temperature rising in the flow direction. This difference is more significant in the parallel flow MCHS which is much colder close to the inlet side than the counter flow arrangement. This result emphasizes the capability of the heat pipes to operate well in asymmetrical heating and cooling load conditions.

### Conclusions

The performance of MCHSs with rectangular and triangular channel cross-sections and counter flow direction in adjacent channels are investigated and compared with double-layer MCHSs with parallel and counter flow arrangements. The study is performed for both Silicon-Water and Copper-Water MCHSs, to investigate the impact of MCHS solid material. The maximum temperature, surface temperature gradient, and thermal resistance of the studied MCHSs are compared. The main findings and conclusions are presented below.

The investigated configuration of Silicon-Water Counter Dual MCHS with rectangular cross-section reduces the surface temperature gradient of the heat sink by 43-50% and 26-31% compared to DL MCHSs with parallel and counter flow configuration, respectively. The triangular cross-section reduces it by 38-47% for parallel and 21-26% for counter flow arrangement, respectively. The studied Counter Dual MCHSs reduce the thermal resistance of heat sinks by 10-15% compared to DL-MCHS with parallel flow arrangement and by 2-8% compared to counter flow arrangement one. A similar improvement trend is obtained for Copper-Water MCHSs. The Counter Dual MCHSs with rectangular and triangular cross-sections require up to 15% and 30-40% lower pumping power, respectively, at 50-400 ml/min flow rates. They both deliver the highest Reynolds number as well.

Innovative hybrid heat sink designs that combine MCHS and FPM-HP technologies are optimized to improve thermal and hot spot management in electronic cooling applications with local high heat generation at the base. The hybrid heat sink is investigated for both parallel and counter flow configurations. The studied cases include cooling of electronic substrate that generates 100 W/cm² as background heat flux and high local heat flux of 1000 W/cm² at the centerline of the base. The performance of the hybrid heat sinks is compared with double-layer MCHSs with a copper heat spreader at the base and with no heat spreader at all (short base). The heat sinks' maximum temperature and surface temperature gradient at various pumping powers are compared. The following conclusions were corroborated within the scope of this work.

The hybrid heat sinks combined with MCHS & FPM-HP proposed and investigated in this work have the lowest maximum temperature and surface temperature gradient among all the studied designs. Hybrid parallel flow configuration has an improved maximum temperature, compared to counter flow configuration ones. However, the hybrid counter flow arrangements are superior in terms of temperature uniformity at the base.

The hybrid DLPF-MCHS & FLM-HP has the lowest maximum temperature followed by the hybrid heat sinks with DLCF and with Counter Dual Rectangular MCHSs compared to the rest of the studied heat sinks. While the hybrid Counter Dual MCHS & FPM-HP has the lowest surface temperature gradient followed by the hybrid heat sinks with DLCF and with Counter Dual Triangular MCHSs. The hybrid DLPF-MCHS & FPM-HP reduces the maximum temperature and surface temperature gradient of the heat sink by 13-23% and 20-49%, while these are reduced by 16-40% and 27-64% for the DLCF-MCHS & FPM-HP compared with the corresponding copper base (no heat pipe) designs.

The hybrid Counter Dual Rectangular MCHS & FPM-HP reduces the maximum temperature and surface temperature gradient of the heat sink by 15-24% and 29-65%, while these are reduced by 10-26% and 24-63% for the Counter Dual Triangular MCHS, respectively, compared with the DLCF MCHS with copper base (no heat pipe) design. The vapor and liquid velocity field in the heat pipes attached to the counter flow MCHSs are similar in trend and magnitude. In all studied hybrid heat sinks, the heat pipe's bottom surface acts as an evaporator, and its top surface acts as a condenser section.

Two sets of coolant circulating loops occur mainly in the heat pipes in this study. The primary circulating loops occur in the vertical cross-sections (xy planes). The local high heat source at the center of the heat pipe base imposes secondary circulating loops of the water which occur from the bottom center of the heat pipe to the top right and top left side of the heat pipe. The secondary water circulating loop to one side of the heat pipe is more significant than the other, due to the asymmetric nature of the cooling in the MCHS, with coolant temperature rising in the flow direction. This difference is more significant in the parallel flow MCHS which is much colder close to the inlet side than the counter flow arrangement. This result emphasizes the capability of the heat pipes to operate well in asymmetrical heating and cooling load conditions.

It will be appreciated that variations of the above-disclosed and other features and functions, or alternatives thereof, may be desirably combined into many other different systems or applications. It will also be appreciated that various presently unforeseen or unanticipated alternatives, modifications, variations or improvements therein may be subsequently made by those skilled in the art which are also intended to be encompassed by the following claims.

### NOMENCLATURE

\vec{V}: velocity, m/s
T: temperature, K
ρ: density, kg/m
p: pressure, Pa
μ: dynamic viscosity, N·s/m²
Nu: Nusselt number
h: heat transfer coefficient, W/m²·K
d_{H}: hydraulic diameter, m
k: thermal conductivity, W/m·K
k_{eff}: effective thermal conductivity, W/m·K
Cₚ: specific heat at constant pressure, J/kg·K
f: Darcy friction factor
Re: Reynolds number
R_{T}: thermal resistance, K/W
q″: heat flux, W/m²
A: area, m²
\dot{m}: mass flow rate, kg/s
h_{fg}: latent heat of evaporation, J/kg
ε: porosity
K: permeability
AR: aspect ratio

### Subscript

f: fluid
g: gas
l: liquid
S: solid
v: vapor

What is claimed is:

1. A heat sink, comprising:
a microchannel heat sink (MCHS).

2. A heat sink, comprising:
a flat plate micro heat pipe (FPM-HP).

3. A hybrid heat sink, comprising:
a microchannel heat sink (MCHS); and
a flat plate micro heat pipe (FPM-HP), wherein the MCHS and FPM-HP are combined to optimize hotspot management in electronics cooling applications that involve local high heat generation.

4. The hybrid heat sink of claim 3 wherein the MCHS and FPM-HP are combined in a parallel flow configuration.

5. The hybrid heat sink of claim 3 wherein the MCHS and FPM-HP are combined in a counter flow configuration.
